(19) United States
(12) Patent Application Publication
(10) Pub. No.: US 2010/0098851 A1
(43) Pub. Date: Apr. 22, 2010

(54) TECHNIQUES FOR ATOMIC LAYER DEPOSITION

(75) Inventors: Shigemi MURAKAWA, Sakura-shi (JP); Vikram Singh, North Andover, MA (US); George Papasouliotis, North Andover, MA (US); Joseph C. Olson, Beverly, MA (US); Paul J. Murphy, Reading, MA (US); Gary E. Dickerson, Gloucester, MA (US)

Correspondence Address: HUNTON & WILLIAMS LLP/VARIAN SEMICONDUCTOR,;EQUIPMENT ASSOCIATES, INC., INTELLECTUAL PROPERTY DEPARTMENT, 1900 K STREET, N.W., SUITE 1200, WASHINGTON, DC, 20006-1109, US

(73) Assignee: VARIAN SEMICONDUCTOR EQUIPMENT ASSOCIATES, INC., GLOUCESTER, MA (US)

(21) Appl. No.: 12/254,496

(22) Filed: Oct. 20, 2008

(51) Int. Cl. C23C 16/44; C23C 16/54

(52) U.S. Cl. 427/248.1; 118/715

(57) ABSTRACT

Techniques for atomic layer deposition (ALD) are disclosed. In one particular exemplary embodiment, the techniques may be realized as a system for ALD comprising a plurality of reactors in a stacked configuration, wherein each reactor comprises a wafer holding portion for holding a target wafer, a gas assembly coupled to the plurality of reactors and configured to provide at least one gas to at least one of the plurality of reactors, and an exhaust assembly coupled to the plurality of reactors and configured to exhaust the at least one gas from the at least one of the plurality of reactors. The gas assembly may further comprise a valve assembly coupled to each of the first gas inlet, the second gas inlet, and the third gas inlet, where the valve assembly is configured to selectively release at least one of the first gas, the second gas, and the third gas.

### FIELD OF THE DISCLOSURE

The present disclosure relates generally to semiconductor manufacturing and, more particularly, to techniques for atomic layer deposition.

### BACKGROUND OF THE DISCLOSURE

Modern semiconductor manufacturing has created a need for precision, atomic-level deposition of high quality thin film structures. Responsive to this need, a number of film growth techniques collectively known as “atomic layer deposition” (ALD) or “atomic layer epitaxy” (ALE) have been developed in recent years. ALD technology is capable of depositing uniform and conformal films with atomic layer accuracy. A typical ALD process uses sequential self-limiting surface reactions to achieve control of film growth in a monolayer thickness regime. Due to its excellent potential for low temperature and high conformity/uniformity of a film, ALD has become the technology of choice for advanced applications such as high dielectric constant (high-k) gate oxide, storage capacitor dielectrics, and high aspect ratio fill in microelectronic devices. In fact, ALD technology may be useful for any advanced application that benefits from precise control of thin film structures on the nanometer (nm) or sub-nanometer scales.

However, conventional ALD techniques may suffer from various deficiencies and have not found widespread adoption in the semiconductor industry. For example, a single wafer ALD process may tend to be slow due to numerous repeated cycles of reactions. This may result in low productivity due to a throughput of only several wafers per hour.

In a batch ALD process, productivity may appear to be substantially increased since a furnace reactor that accommodates the batch ALD process may support approximately 100 wafers. However, overall productivity remains comparable to that of the single ALD process because cycle time increases due to the large volume of the furnace reactor. In addition, the batch ALD process may not have as much process flexibility or clustering capability when compared to other conventional ALD processes.

A semi-batch ALD process having a planar reactor may also be used to process a plurality of wafer at the same time. Although there may be some improvement in productivity, such improvement remains minimal.

In view of the foregoing, it may be understood that there are significant problems and shortcomings associated with current atomic layer deposition (ALD) technologies.

### SUMMARY OF THE DISCLOSURE

Techniques for atomic layer deposition (ALD) are disclosed. In one particular exemplary embodiment, the techniques may be realized as a system for atomic layer deposition (ALD) comprising a plurality of reactors in a stacked configuration, wherein each reactor comprises a wafer holding portion for holding a target wafer, a gas assembly coupled to the plurality of reactors and configured to provide at least one gas to at least one of the plurality of reactors, and an exhaust assembly coupled to the plurality of reactors and configured to exhaust the at least one gas from the at least one of the plurality of reactors.

In accordance with other aspects of this particular exemplary embodiment, the stacked configuration may be a vertically stacked configuration such that the plurality of reactors are stacked on top of one another.

In accordance with further aspects of this particular exemplary embodiment, the stacked configuration may be a horizontally stacked configuration such that the plurality of reactors are stacked next to one another.

In accordance with additional aspects of this particular exemplary embodiment, the gas assembly may comprise a first gas inlet configured to provide a first gas to the plurality of reactors, a second gas inlet configured to provide a second gas to the plurality of reactors, and a third gas inlet configured to provide a third gas to the plurality of reactors.

In accordance with other aspects of this particular exemplary embodiment, the first gas may be a first reactive gas, the second gas may be a second reactive gas, and the third gas is an inert gas.

In accordance with further aspects of this particular exemplary embodiment, the gas assembly may further comprise a valve assembly coupled to each of the first gas inlet, the second gas inlet, and the third gas inlet, wherein the valve assembly may be configured to selectively release at least one of the first gas, the second gas, and the third gas.

In accordance with additional aspects of this particular exemplary embodiment, the valve assembly may be in a vertical valve configuration, the valve assembly may further comprise a first set of nozzles configured to selectively release the first gas in a plane substantially parallel to a surface of the target wafer, a second set of nozzles configured to selectively release the second gas in a plane substantially parallel to a surface of the target wafer, and a third set of nozzles configured to selectively release the third gas in a plane substantially parallel to a surface of the target wafer, such that the first set of nozzles, the second set of nozzles, and the third set of nozzles may be stacked on top of each other.

In accordance with other aspects of this particular exemplary embodiment, the valve assembly may be in a horizontal valve configuration, the valve assembly further comprising a first set of nozzles configured to selectively release the first gas in a plane substantially parallel to a surface of the target wafer, a second set of nozzles configured to selectively release the second gas in a plane substantially parallel to a surface of the target wafer, and a third set of nozzles configured to selectively release the third gas in a plane substantially parallel to a surface of the target wafer, such that the second set of nozzles may be positioned adjacent to the first set of nozzles, and the third set of nozzles may be positioned adjacent to the second set of nozzles.

In accordance with further aspects of this particular exemplary embodiment, the valve assembly may be configured to release gas from the at least one of the first set of nozzles, the second set of nozzles, and the third set of nozzles such that the release gas substantially covers an entire surface of the target wafer.

In accordance with additional aspects of this particular exemplary embodiment, the first set of nozzles, the second set of nozzles, and the third set of nozzles may be alternatively positioned such that gas released from one nozzle may be different than gas released from nozzles immediately adjacent the one nozzle.

In accordance with other aspects of this particular exemplary embodiment, the valve assembly may use a rod valve to selectively release at least one of the first gas, the second gas, and the third gas.

In accordance with further aspects of this particular exemplary embodiment, the exhaust assembly may comprise a first exhaust line configured to exhaust at least one gas from a side opposite that of where the at least one gas may be provided.

In accordance with additional aspects of this particular exemplary embodiment, the gas assembly may further comprise a fourth gas inlet configured to provide a fourth gas to the plurality of reactors, such that the first gas inlet and the third gas inlet may be positioned on a first side of the wafer and the second gas inlet and the fourth gas inlet may be positioned on a second side of the wafer, where the second side may be opposite to the first side.

In accordance with other aspects of this particular exemplary embodiment, the exhaust system may further comprise a first exhaust line and a second exhaust line, such that the first exhaust line may be positioned on the second side and the second exhaust line may be positioned on the first side in order to exhaust gas from the plurality of reactors in a counter-flow scheme to improve uniformity.

In another particular exemplary embodiment, the techniques may be realized as a method for atomic layer deposition (ALD) comprising releasing a first gas into a chamber of each of a plurality of reactors in order to provide atomic layer deposition of a first species, exhausting at least the first gas from the chamber while the first gas is being released into the chamber, and releasing an inert gas into the chamber to purge the chambers of the first gas.

In accordance with other aspects of this particular exemplary embodiment, the method may further comprise exhausting at least the inert gas from the chamber while the inert gas is being released into the chamber.

In accordance with further aspects of this particular exemplary embodiment, the method where exhausting at least the first gas may begin simultaneously with the release of the first gas.

In accordance with additional aspects of this particular exemplary embodiment, the method where exhausting at least the first gas may begin after a predetermined time lag after the release of the first gas.

In accordance with other aspects of this particular exemplary embodiment, the method where exhausting at least the first gas may be continuous once the at least the first gas is exhausted from the chamber while the first gas is being released into the chamber.

In accordance with further aspects of this particular exemplary embodiment, the method where exhausting at least the first gas may be achieved from a side of the chamber opposite that of a side where the first gas is released.

In accordance with additional aspects of this particular exemplary embodiment, the method may further comprise releasing a second gas into the chamber in order to provide atomic layer deposition of a second species, exhausting at least the second gas from the chamber while the second gas is being released into the chamber, and releasing an inert gas into the chamber to purge the chamber of the second gas.

In accordance with other aspects of this particular exemplary embodiment, the second gas may be released from a side of the chamber opposite that of a side where the first gas is released.

In accordance with further aspects of this particular exemplary embodiment, the method may further comprise exhausting at least the inert gas from the chamber while the inert gas is being released into the chamber.

In accordance with additional aspects of this particular exemplary embodiment, the method where exhausting at least the second gas may begin simultaneously with the release of the second gas.

In accordance with other aspects of this particular exemplary embodiment, the method where exhausting at least the second gas may begin after a predetermined time lag after the release of the second gas.

In accordance with further aspects of this particular exemplary embodiment, the method where exhausting at least the second gas may be continuous once the at least second gas is exhausted from the chamber while the second gas is being released into the chamber.

In accordance with additional aspects of this particular exemplary embodiment, the method where exhausting gas may be achieved from a side of the chamber opposite that of a side where the second gas is released.

The present disclosure will now be described in more detail with reference to exemplary embodiments thereof as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIGS. 1A-1B depict an atomic layer deposition (ALD) configuration according to an embodiment of the present disclosure.

FIGS. 2A-2G depict a gas valve configuration according to various embodiments of the present disclosure.

FIGS. 3A-3B depict a gas valve configuration according to other embodiments of the present disclosure.

FIG. 4 depicts an exemplary graph illustrating a cycle for atomic layer deposition (ALD) according to an embodiment of the present disclosure.

FIGS. 5A-5B depict exemplary graphs illustrating the effects of performing atomic layer deposition (ALD) according to an embodiment of the present disclosure.

FIGS. 6A-6C depict an atomic layer deposition (ALD) configuration according to another embodiment of the present disclosure.

FIG. 7 depicts an exemplary graph illustrating a cycle for atomic layer deposition (ALD) according to an embodiment of the present disclosure.

FIGS. 8A-8B depict various exemplary atomic layer deposition (ALD) module configurations according to another embodiment of the present disclosure.

### DETAILED DESCRIPTION OF EXEMPLARY EMBODIMENTS

Reference will now be made in detail to exemplary embodiments, examples of which are illustrated in the accompanying drawings. It should be appreciated that the same reference numbers may be used throughout the drawings to refer to the same or like parts. It should be appreciated that the following detailed description is exemplary and explanatory only and is not restrictive.

Embodiments of the present disclosure provide techniques for atomic layer deposition (ALD). In addition, embodiments of the present disclosure provide various exemplary configurations for atomic layer deposition (ALD).

To solve the aforementioned problems associated with conventional atomic layer deposition techniques, embodiments of the present disclosure improve ALD productivity by introducing a stacked ALD configuration. Here, uniform flow and rapid gas delivery may be provided to each reactor to improve uniformity and repeatability of film thickness at sufficient levels.

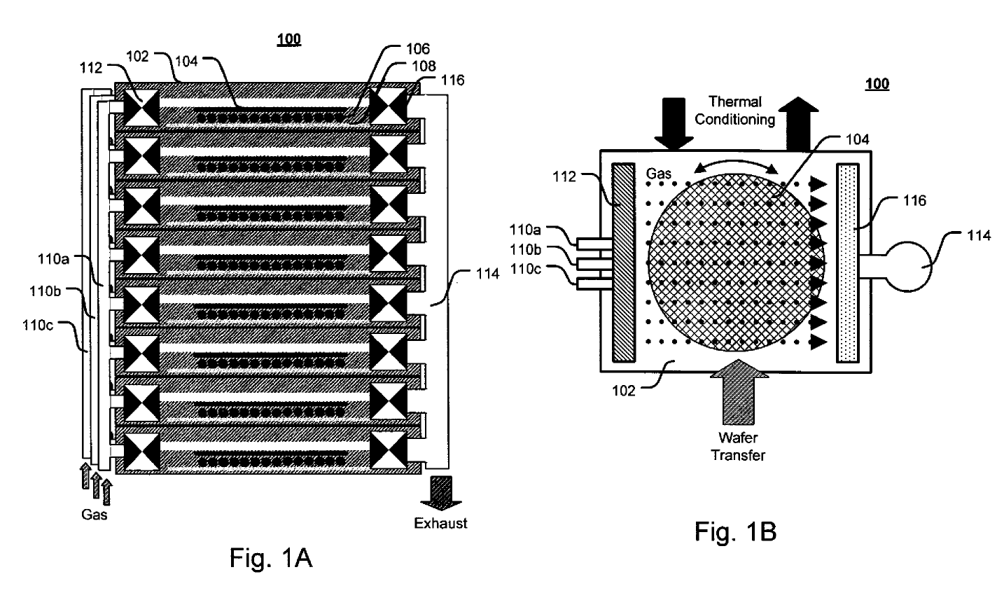

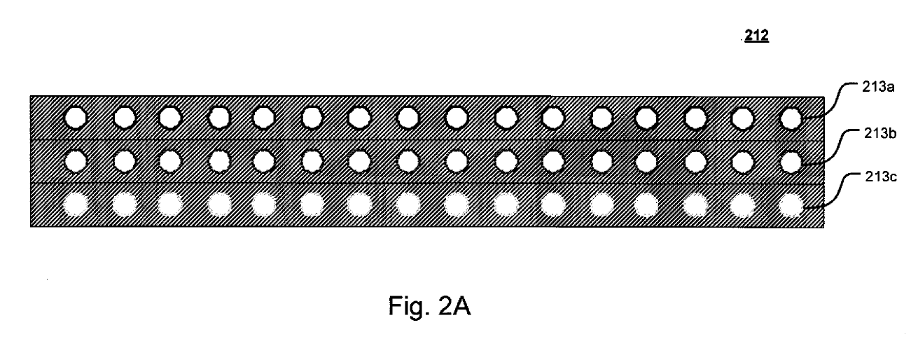

Referring to FIG. 1A, a side view of an atomic layer deposition (ALD) configuration 100 according to an embodiment of the present disclosure is depicted. The ALD configuration 100 may be a stacked configuration comprising a plurality of reactors 102 stacked on top of one another. Each of the plurality of reactors 102 may comprise a wafer 104 positioned over one or more heating elements 106 and a thermal element 108. The one or more heating elements 106 and the thermal element 108 may provide thermal conditioning for optimum ALD processing at each of the plurality of reactors 102.

The ALD configuration may also comprise a plurality of gas inlets 110a, 110b, and 110c coupled to each of the plurality of reactors 102. At each of the plurality of reactors 102, a gas valve 112 may be provided to control gas flow over the wafer 104 in the plurality of reactors 102. At the opposite end of the plurality of gas inlets 110a, 110b, and 110c, an exhaust line 114 may be provided. An exhaust valve 116 may also be provided at each of the plurality of reactors 102 to control gas flow out of each of the plurality of reactors 102. Other various embodiments may also be provided.

At each of the plurality of reactors 102, the gas valve 112 and/or the exhaust valve 116 may be used to control gas flow. In some embodiments, gas flow may be controlled by various combinations of turning on/off the gas valve 112 and/or the exhaust valve 116. It should be appreciated that the gas valve 112 and/or the exhaust valve 116 may be positioned near a reaction chamber or space of each of the plurality of reactors 102. Such proximity may be particularly advantageous for precise control of gas volume/flow over the wafer 104.

In one embodiment, there may be three gas inlets. For example, a first gas inlet 110a may provide a first gas (e.g., a first reactant gas) to the reaction chamber of each of the plurality of reactors 102 via the gas valve 112, a second gas inlet 110b may provide a second gas (e.g., a second reactant gas) to the reaction chamber of the reactor 102 via the gas valve 112, and a third gas inlet 110c may provide a third gas (e.g., an inert gas) to the reaction chamber of the reactor 102 via the gas valve 112. In this example, the first gas and the second gas may be used to provide ALD reactions and the third gas may be used to purge the reaction chamber of the reactive gases (e.g., the first gas and/or the second gas).

In one embodiment, for example, there may be several gas flow combinations turning on or turning off the various gas inlets 110a, 110b, and 110c. In a first position (e.g., position 1), only the first gas inlet 110a may be opened to release a first reactive gas (e.g., reactive gas A). In a second position (e.g., position 2), only the second gas inlet 110b may be opened to release a second reactive gas (e.g., reactive gas B). In a third position (e.g., position 3), only the third gas inlet 110c may be open to release a third gas (e.g., inert gas N). In a fourth position (e.g., position 4), all gas inlets 110a/110b, and 110c may be closed. The exhaust valve may have an open position and a closed position. Other various embodiments may also be provided.

It should be appreciated that while embodiments of the present disclosure are directed to using three gas inlets 110a, 110b, and 110c to supply three gases, other various embodiments may also be provided. For example, a greater or lesser number of gas inlets, exhaust lines, gases, and/or configurations may also be provided.

FIG. 1B depicts a top view of the atomic layer deposition (ALD) configuration 100 according to an embodiment of the present disclosure. In this view, the wafer 104 may be transferred to the reactor 102 at a side adjacent to the plurality of gas inlets 110a, 110b, and 110c and/or the exhaust line 114. Also in this view, thermal conditioning (e.g., heat transfer) of the reactor 102 may be conducted through another side of the reactor 102. It should be appreciated that the wafer 104 may also be rotated (e.g., about a center) (as depicted by curved arrows in FIG. 1B). This may be achieved via a platen, platform, or other similar assembly (not shown).

It should also be appreciated that although the plurality of gas inlets 110a, 110b, and 110c are positioned opposite to that of the exhaust line 114, other various configurations may also be provided. For example, in some embodiments, the exhaust line 114 may be on the same side as the plurality of gas inlets 110a, 110b, and 110c, adjacent to the plurality of gas inlets 110a, 110b, and 110c, on the opposite side of the plurality of gas inlets 110a, 110b, and 110c or a combination thereof.

Although the ALD configuration 100 is depicted in a vertical configuration (e.g., where reactors are vertically stacked on one another), it should be appreciated that reactors 102 may also be stacked in a horizontal configuration. Other stacking configurations that minimize volume and/or space may also be provided.

An advantage of using the stacked ALD configuration 100, as described above, may improve ALD productivity. For example, reaction space at each reactor 102 may be reduced. Such reduction may improve timing and/or control of gas flow within the reactor 102. Additionally, smaller reaction chambers may also allow better control of thermal conditions and/or reductions in the amount of reactive gases that are used. Furthermore, by stacking reactors 102 (e.g., vertically, horizontally, etc.) with smaller chambers or reactive spaces, overall volume may be reduced. Thus, a greater number of wafers may be subject to ALD without sacrificing quality and control.

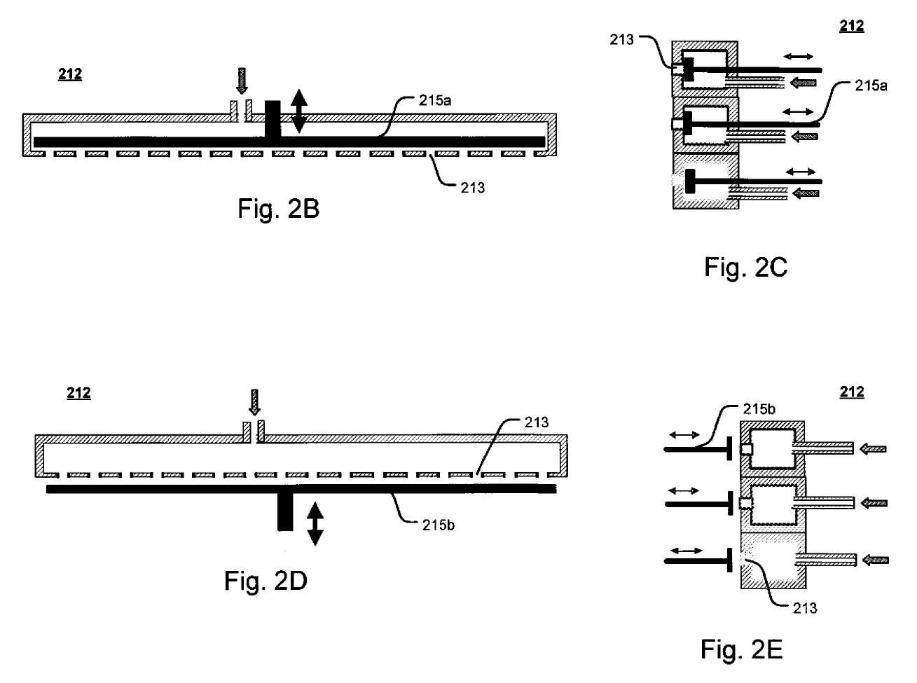

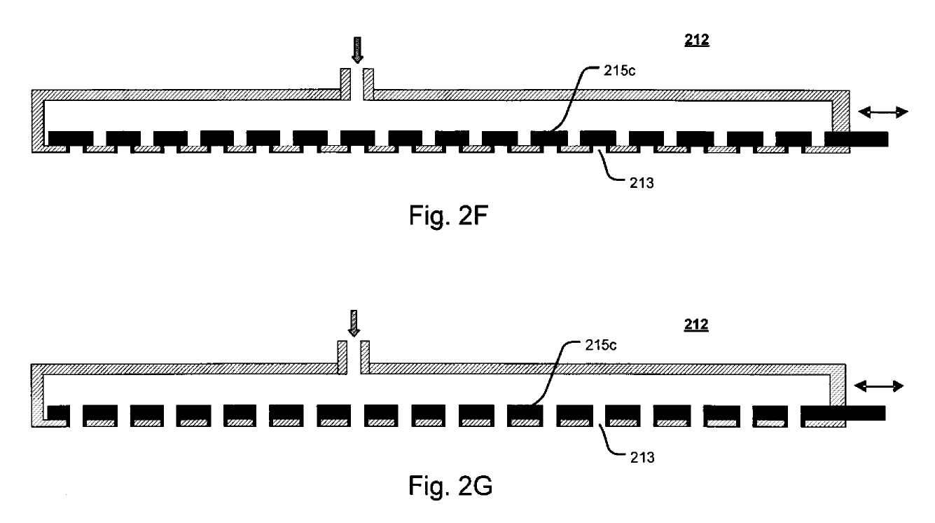

Referring to FIG. 2A, a frontal view of a vertical gas valve configuration 212 according to various embodiments of the present disclosure is depicted. Here, the vertical gas valve configuration 212 may comprise a set of nozzles 213 for each gas and/or gas inlet. For example, a first set of nozzles 213a may be vertically placed on top of a second set of nozzles 213b, which may in turn be placed on top of a third set of nozzles 213c. In one embodiment, the first set of nozzles 213a may correspond to the first gas inlet 110a, the second set of nozzles 213b may correspond to the second gas inlet 110b, and the third set of nozzles 213c may correspond to the third gas inlet 110c. Accordingly, flow of the various gases (e.g., reactive gas A, reactive gas B, inert gas N, etc.) into the reaction chamber of each of the plurality of reactors 102 may be easily controlled using the vertical valve configuration 212.

FIG. 2B depicts a top view of the vertical gas valve configuration 212 using a rod valve 215 according to an embodiment of the present disclosure. In this example, the nozzles 213 may be controlled (e.g., opened or closed) by a rear rod valve 215a. The rear rod valve 215a may be positioned behind the nozzles 213 and actuated by sliding in a direction horizontal to gas flow (as depicted by arrows in FIG. 2B). Accordingly, at an extended position, the nozzles 213 may be closed, and at a retracted position, the nozzles 213 may be opened.

FIG. 2C depicts a side view of the vertical gas valve configuration 212 using the rear rod valve 215a according to an embodiment of the present disclosure. In this view, the rear rod valve 215a is shown behind each set of nozzles 213. In one embodiment, each rear rod valve 215a may be independently controlled (as depicted by arrows in FIG. 2C).

FIG. 2D depicts a top view of the vertical gas valve configuration 212 using a rod valve 215 according to another embodiment of the present disclosure. In this example, the nozzles 213 may be controlled (e.g., opened or closed) by a front rod valve 215b. The front rod valve 215b may be S positioned in front of the nozzles 213 and actuated by sliding in a direction horizontal to gas flow (as depicted by arrows in FIG. 2D). Accordingly, at an extended position, the nozzles 213 may be closed, and at a retracted position, the nozzles 213 may be opened.

FIG. 2E depicts a side view of the vertical gas valve configuration 212 using the front rod valve 215b according to an embodiment of the present disclosure. In this view, a front rod valve 215a is shown behind each set of nozzles 213. In one embodiment, each front valve 215b may be independently controlled (as depicted by arrows in FIG. 2E).

FIGS. 2F-2G depict top views of the vertical gas valve configuration 212 using a rod valve 215 according to another embodiment of the present disclosure. In this example, the nozzles 213 may be controlled (e.g., opened or closed) by a sliding rod valve 215c. The sliding rod valve 215c may be positioned behind (or in front of) the nozzles 213 and actuated by sliding in a direction perpendicular to gas flow (as depicted by arrows in FIGS. 2F-2G). The sliding rod valve 215c may have holes that correspond or match the nozzles 213. In a closed positioned, the holes of the sliding rod valve 215c may be staggered and therefore not match up with the nozzles, as depicted in FIG. 2F. Here, gas may be prevented from flowing into the reaction chamber of the reactor 102. In an opened position, however, the sliding rod valve 215c may be positioned so that the holes of the sliding rod valve 215c match up with the nozzles, as depicted in FIG. 2G. Here, gas may be allowed to flow into the reaction chamber of the reactor 102. It should be appreciated that the sliding valve 215c of each set of nozzles may also be independently controlled.

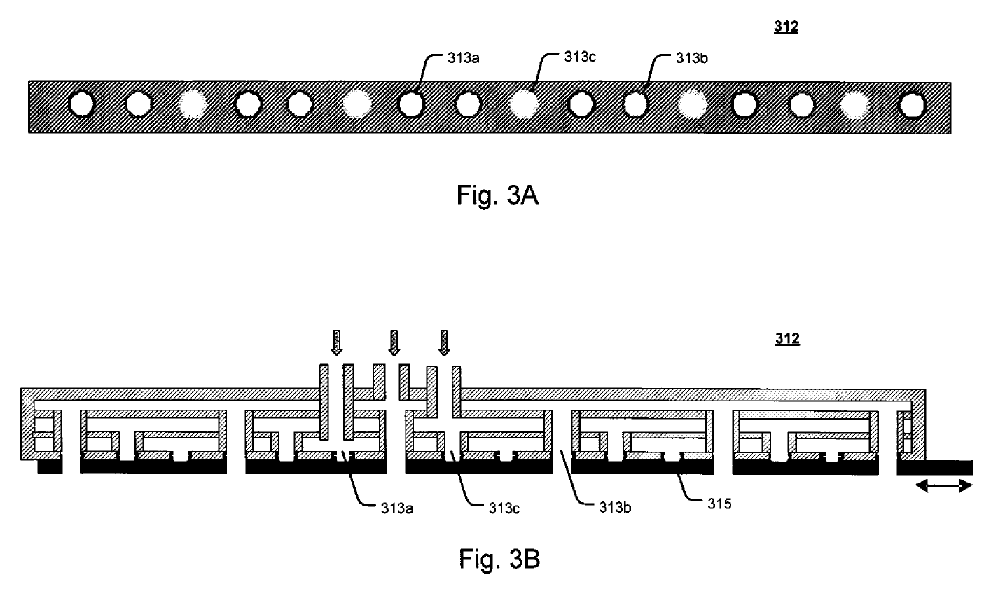

Referring to FIG. 3A, a frontal view of a horizontal gas valve configuration 312 according to an embodiment of the present disclosure is depicted. Here, the horizontal gas valve configuration 312 may comprise a nozzle 313 for each gas and/or gas inlet adjacent to another nozzle 313 for another gas and/or gas inlet. For example, in a configuration using three gases and/or three gas inlets, a first nozzle 313a may be placed horizontally and adjacent to a second nozzle 313b, which in turn may be placed horizontally and adjacent to a third nozzle 313c. In one embodiment, the first nozzle 313a may correspond to the first gas inlet 110a, the second nozzle 313b may correspond to the second gas inlet 110b, and the third nozzle 313c may correspond to the third gas inlet 110c. This alternating pattern may be repeated along the entire length of the horizontal gas valve configuration 312. Accordingly, flow of the various gases (e.g., reactive gas A, reactive gas B, inert gas N, etc.) into the reaction chamber of each of the plurality of reactors 102 may be controlled using the horizontal valve configuration 312.

For example, FIG. 3B depicts a top view of the horizontal gas valve configuration 312 using a rod valve 315 according to an embodiment of the present disclosure. In this example, the nozzles 313a, 313b, and 313c may be controlled (e.g., opened or closed) by using a sliding rod valve 315. In one embodiment, the sliding rod valve 315 may be positioned in front of the nozzles 313a, 313b, and 313c and actuated by sliding in a direction perpendicular to gas flow (as depicted by arrows in FIG. 3B). In a configuration using three gases and/or three gas inlets, the sliding rod valve 315 may have holes that correspond or match every three nozzles. For example, the gas inlet 110b may output reactive gas B at the nozzle 313b. The nozzle 313b may repeat every three nozzles along the horizontal valve configuration 312. In an open position (e.g., where the holes of the sliding rod valve 315 may be actuated in a direction perpendicular to gas flow (see arrows) to match up with the reactive gas B nozzles, e.g., nozzle 313b ), the other nozzles (e.g., nozzle 313a for reactive gas A and nozzle 313c for inert gas N) may be blocked in a closed positioned since no holes match up with these nozzles. Accordingly, for any nozzle of a particular gas and/or gas inlet in an open position, the nozzles of other gases and/or gas inlets may be in a closed position.

It should be appreciated that while embodiments of the present disclosure are directed to using rod valves and/or sliding valves to turn of/off the nozzles for three different gases, on/off valves and/or multi-position (e.g., three-position) valves may also be placed at the gas lines which are proximate to the nozzles.

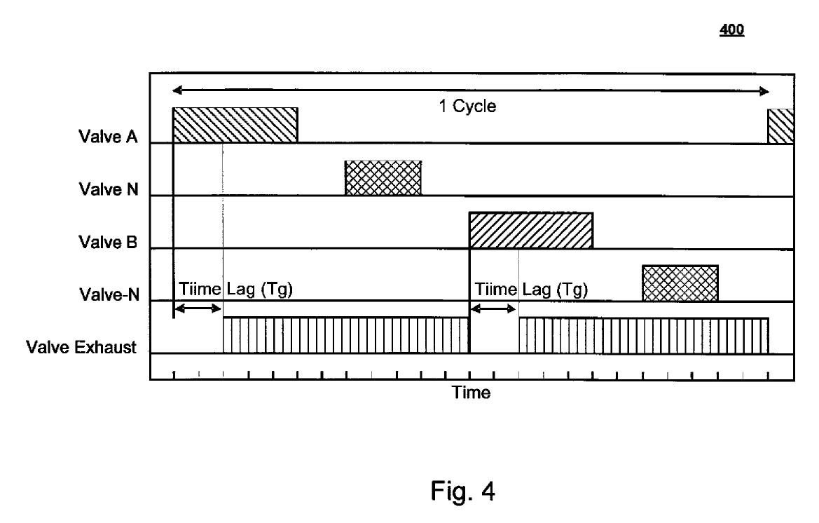

FIG. 4 depicts an exemplary graph 400 illustrating a cycle for atomic layer deposition (ALD) according to an embodiment of the present disclosure. In the graph 400, each block may represent an amount of time a particular valve is opened. At the beginning of one cycle, the valve (e.g., Valve A) corresponding to the first reactive gas (e.g., reactive gas A) may be opened to introduce reactive gas A into each of the plurality of reactors 102. In some embodiments, the exhaust valve may be opened at the same time as when Valve A is opened or shortly thereafter (e.g., after a predetermined time lag (Tg)), as depicted in FIG. 4. It should be appreciated that when there is no time lag, Tg may be zero (0). By opening the exhaust valve simultaneously with Valve A or some time thereafter, laminar flow may created. This may allow the gas, e.g., reactive gas A, to cover and adhere to the wafer 104 with greater uniformity.

After a predetermined time period of ALD processing with the first reactive gas, Valve A may be closed while the exhaust valve is left open to exhaust the first reactive gas from the chamber of each of the plurality of reactors 102. In some embodiments, exhausting reactive gas A in this manner may be eliminated. In other embodiments, the valve (e.g., Valve N) corresponding to an inert gas (e.g., inert gas N) may be opened to introduce inert gas N into each of the plurality of reactors 102 while the exhaust valve remains open. This may serve to purge any residual first reactive gas (e.g., reactive gas A) remaining in the reaction chamber of each of the plurality of reactors 102.

Once reactive gas A is purged by the flow of inert gas N, the valve N may be closed while the exhaust is kept open. This may serve to exhaust the remaining inert gas before introducing a second reactive gas. In some embodiments, exhausting inert gas N in this manner may be eliminated.

Once the second reactive gas is ready to be introduced, the valve (e.g., Valve B) corresponding to the second reactive gas (e.g., reactive gas B) may be opened to introduce reactive gas B into each of the plurality of reactors 102. In some embodiments, the exhaust valve may be opened at the same time as when Valve B is opened or shortly thereafter (e.g., after a predetermined time lag (Tg)), similar to as described above. By opening the exhaust valve simultaneously with Valve B or some time thereafter, laminar flow may created. This may allow the gas, e.g., reactive gas B, to cover and adhere to the wafer 104 with greater uniformity.

After a predetermined time period of ALD processing with the second reactive gas, Valve B may be closed while the exhaust valve is left open to exhaust the second reactive gas from the chamber of each of the plurality of reactors 102. In some embodiments, exhausting reactive gas B in this manner may be eliminated. In other embodiments, the valve (e.g., Valve N) corresponding to an inert gas (e.g., inert gas N) may be opened to introduce inert gas N into each of the plurality of reactors 102 while the exhaust valve remains open. This may serve to purge any residual second reactive gas (e.g., reactive gas B) remaining in the reaction chamber of each of the plurality of reactors 102.

Once reactive gas B is purged by the flow of inert gas N, the valve N may be closed while the exhaust is kept open. This may serve to exhaust the remaining inert gas N. In some embodiments, exhausting inert gas N in this manner may be eliminated. At this point, one cycle may be completed and subsequent cycles may commence.

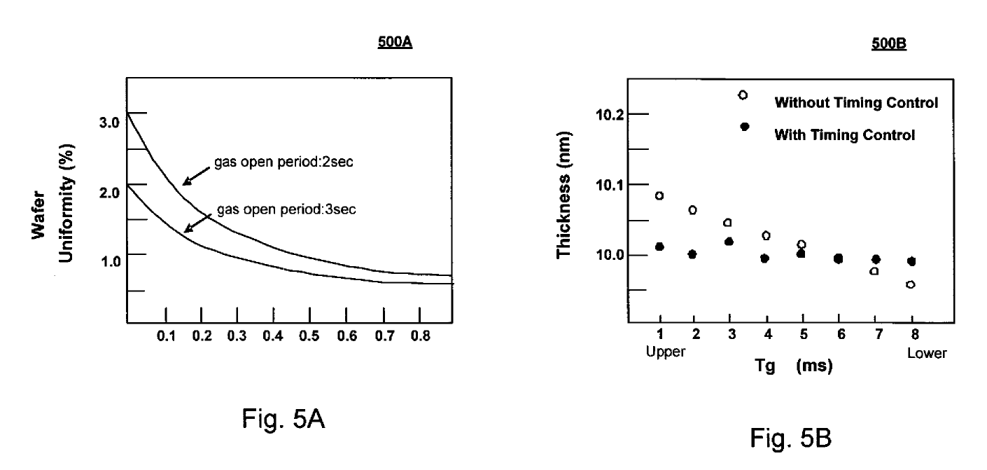

FIGS. 5A-5B depict exemplary graphs illustrating the effects of performing atomic layer deposition (ALD) according to an embodiment of the present disclosure. Referring to FIG. 5A, graph 500A shows that improvement in thickness uniformity on a wafer may be achieved placing a time lag (Tg) between opening a gas inlet valve and opening the exhaust valve. Dependency of the uniformity on the time lag (Tg) may be increased when the period during which the gas inlet valve is open becomes shorter for an ALD cycle. Therefore, controlling timing between the gas inlet valve and the exhaust valve may be an important feature/parameter providing sufficient uniformity during an ALD cycle.

It should also be appreciated that adhesive coverage of a reactive gas may be high near the inlet nozzle and such adhesive coverage may gradually decrease in proportion to a distance further from the inlet nozzle. Accordingly, when a gas inlet valve is open for short period, adhesive coverage may become small at distances from the gas inlet valve. As a result, having a time lag (Tg) may allow reactive gas flowing from the gas inlet valve to diffuse over the wafer for uniform absorption.

Wafer-to-wafer uniformity may also be improved by using such timing control. For example, when the exhaust valve 116 is kept open, film thickness may be dependent on the distance between each of the plurality of reactors 102 and/or a turbo molecular pump (not shown). As depicted in FIG. 5B, graph 500B shows that wafer-to-wafer uniformity may be improved using timing control of the exhaust valve as compared to not using timing control of the exhaust valve.

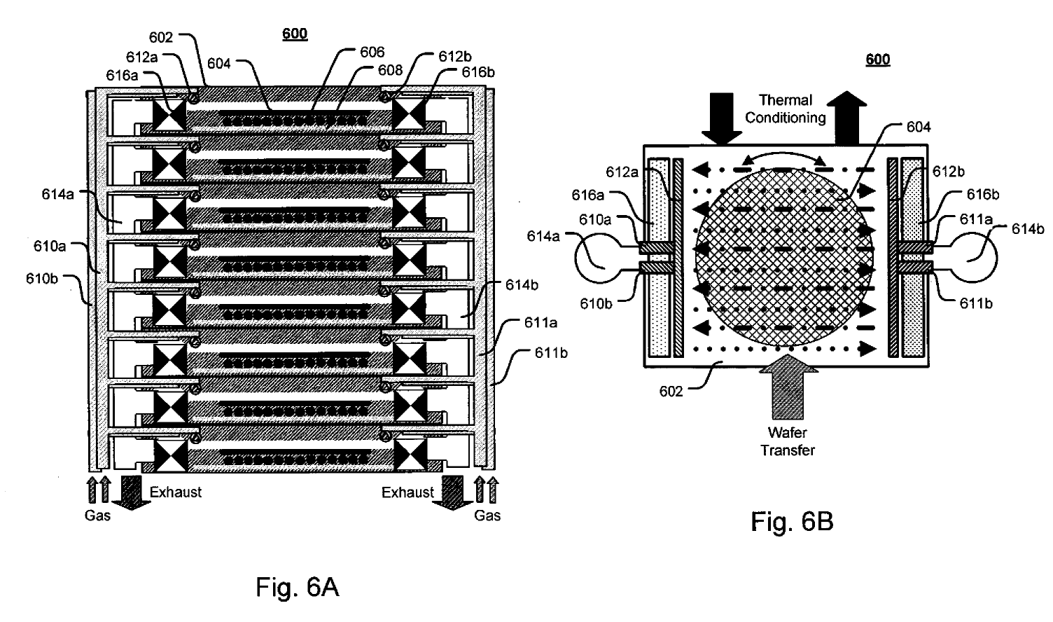

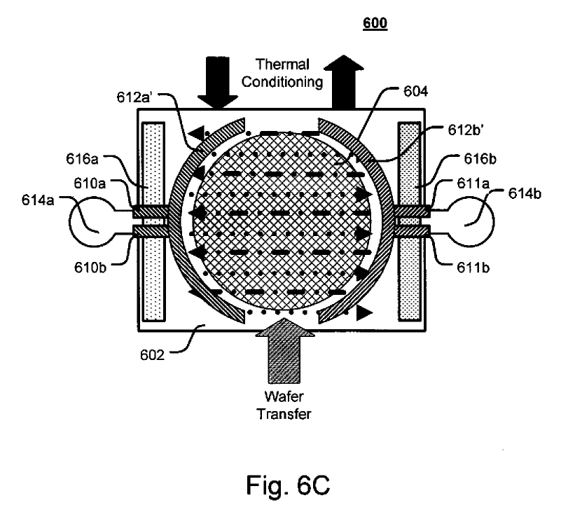

FIGS. 6A-6C depict an atomic layer deposition (ALD) configuration 600 according to another embodiment of the present disclosure. Referring to FIG. 6A, a side view of an atomic layer deposition (ALD) configuration 600 according to another embodiment of the present disclosure is depicted. Similar to the ALD configuration 100 of FIG. 1A, the ALD configuration 600 of FIG. 6 may be a stacked configuration comprising a plurality of reactors 602 stacked on top of one another. Each of the plurality of reactors 602 may comprise a wafer 604 positioned over one or more heating elements 606 and a thermal element 608. The one or more heating elements 606 and the thermal element 608 may provide thermal conditioning for optimum ALD processing at each of the plurality of reactors 602.

However, unlike the ALD configuration 100 of FIG. 1A, the ALD configuration 600 of FIG. 6A may comprise a first set of gas inlets 610a, 610b and a second set of gas inlets 611a, 611b. In addition, the ALD configuration 600 may comprise a first exhaust line 614a and a second exhaust line 614b. In one embodiments, the first set of gas inlets 610a, 610b may be positioned opposite that of the second set of gas inlets 611a, 611b with respect to the reactors 602. In other embodiments, the first exhaust line 614a may be on the same side of the wafer 604 as the first set of gas inlets 610a, 610b, and the second exhaust line 614b may be on the same side of the wafer 604 as the second set of gas inlets 611a, 611b. Other various positions and/or configurations may also be provided.

At a first end of each of the plurality of reactors 602, a first gas valve 612a may be provided to control gas flow from the first set of gas inlets 610a, 610b over the wafer 604 in the reactors 602. At an opposite end of each of the plurality of reactors 602, a second gas valve 612b may be provided to control gas flow (e.g., in the opposite direction) from the second set of gas inlets 611a, 611b over the wafer 604 in the reactors 602. Here, the second exhaust line 614b, which is opposite that of the first gas valve 612a, may control gas flow out from the first set of gas inlets 610a, 610b, and the first exhaust line 614a, which is opposite that of the second gas valve 612b, may control gas flow out from the second set of gas inlets 611a, 611b. Other various embodiments may also be provided.

In some embodiments, gas flow may be controlled by various combinations of turning on/off the gas valves 612a, 612b and/or the exhaust valves 616a, 616b. It should be appreciated that the gas valves 612a, 612b and/or the exhaust valves 616a, 616b may be positioned near a reaction chamber or space of the reactors 602. Such proximity may be particularly advantageous for precise control of gas volume/flow over the wafer 604.

In one embodiment, there may be four gas inlets. For example, the first gas inlet 610a of the first set of gas inlets may provide a first gas (e.g., a first reactant gas) to the reaction chamber of the reactors 602 via the gas valve 612a. The second gas inlet 610b of the first set of gas inlets may provide an inert gas (e.g., inert gas N1) to the reaction chamber of the reactors 602 via the gas valve 612a. The first gas inlet 611a of the second set of gas inlets may provide a second gas (e.g., a first reactant gas) to the reaction chamber of the reactors 602 via the gas valve 612b. The second gas inlet 611b of the second set of gas inlets may provide another inert gas (e.g., inert gas N2) to the reaction chamber of the reactors 602 via the gas valve 612b. In this example, the first gas and the second gas may be used to provide ALD reactions and the inert gases may be used to purge the reaction chamber of the reactive gases (e.g., the first gas and/or the second gas). It should be appreciated that inert gas N1 may be the same or different from inert gas N2. Other various embodiments may also be provided.

In one embodiment, for example, there may be several gas flow combinations turning on or turning off the various gas inlets 610a, 610b, 611a, and 611d so that a first reactive gas (e.g., reactive gas A) may form a counter-flow scheme with a second reactive gas (e.g., reactive gas B) Each gas valve 612 may have several positions: reactive gas open (e.g., position 5), inert gas open (e.g., position 6), and all gas closed (e.g., position 7). Each exhaust valve 616 may have an open position and closed position as well.

It should also be appreciated that although the plurality of gas inlets 610a, 610b, 611a, and 611b are shown positioned opposite to that of the exhaust lines 614a, 614b, respectively, other various configurations may also be provided. For example, in some embodiments, the exhaust lines 616a, 616b may be on the same side as the plurality of gas inlets 110a, 110b, and 110c, adjacent to the plurality of gas inlets 110a, 110b, and 110c, on the opposite side of the plurality of gas inlets 110a, 110b, and 110c, or a combination thereof.

It should be appreciated that while the ALD configuration 600 is directed to using four gas inlets 610a, 610b, 611a, and 611b, two for reactive gases and two for inert gases, other various embodiments may also be provided. For example, a greater or lesser number of gas inlets, exhaust lines, gases, and/or configurations may also be provided.

FIG. 6B depicts a top view of the atomic layer deposition (ALD) configuration 600 according to an embodiment of the present disclosure. In this view, the wafer 604 may be transferred to the reactors 602 at either side adjacent to the plurality of gas inlets 610a, 610b, 611a, and 611b and/or the exhaust lines 614a, 614b. Also in this view, thermal conditioning (e.g., heat transfer) of the reactors 602 may be conducted through another side of the reactors 602. It should be appreciated that the wafer 604 may also be rotated (e.g., about a center of the wafer 604) (as depicted by curved arrows in FIG. 6B). This may be achieved via a platen, platform, or other similar assembly (not shown).

FIG. 6C depicts a top view of the atomic layer deposition (ALD) configuration 600 according to another embodiment of the present disclosure. In this embodiment, unlike the straight gas valves of FIG. 6A-6B, a first gas valve 612a′ and a second gas valve 612b′ may be curved to conform to the edge of the wafer 604. This may provide a more uniform gas flow across a surface of the wafer 604.

An advantage of using the ALD configuration 600, as described above, is that such a configuration may improve ALD quality and productivity. For example, in addition to the benefits described with respect to the ALD configuration 100 of FIGS. 1A-1B, the ALD configuration 600 may provide optimal flow for achieving improved uniformity. By flowing a first reactive gas in a direction counter to a direction of the second reactive gas, quality ALD processing may be achieved.

It should be appreciated that gas flow may be highly controlled. For example, embodiments of the present disclosure may use customized injection points so that gas may be injected across a surface of a wafer at various points across a diameter of a chamber of the reactors 602 and/or at various angles. Other various embodiments may also be provided.

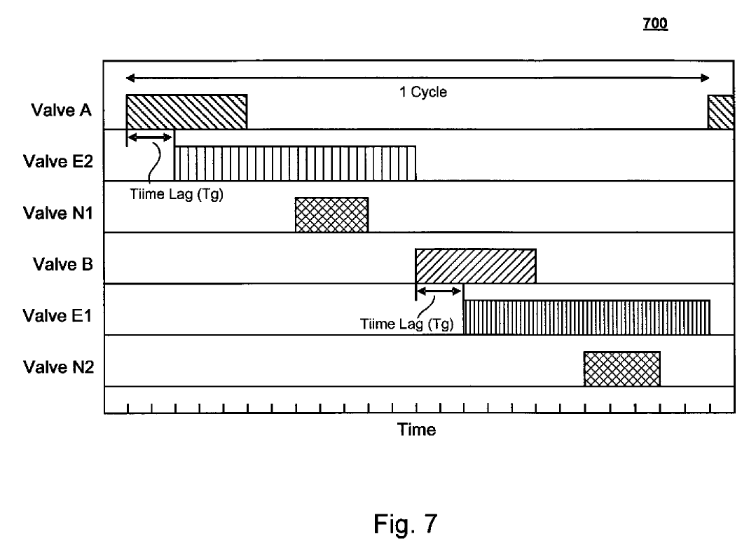

FIG. 7 depicts an exemplary graph 700 illustrating a cycle for atomic layer deposition (ALD) according to an embodiment of the present disclosure. In the graph 700, each block may represent an amount of time a particular valve is opened. At the beginning of one cycle, the first gas valve 610a of the first set of gas valves (e.g., Valve A) corresponding to the first reactive gas (e.g., reactive gas A) may be opened to introduce reactive gas A into the reactors 602. In some embodiments, the second exhaust valve 616b (e.g., Valve E2) may be opened at the same time as when Valve A is opened or shortly thereafter (e.g., after a predetermined time lag (Tg)), as depicted in FIG. 7. It should be appreciated that when there is no time lag, Tg may be zero (0). By opening Valve E2 simultaneously with Valve A or some time thereafter, laminar flow may created. This may allow the gas, e.g., reactive gas A, to cover and adhere to the wafer 604 greater uniformity.

After a predetermined time period of ALD processing with the first reactive gas, Valve A may be closed while Valve E2 is left open to exhaust the first reactive gas from the chamber of the reactors 602. In some embodiments, exhausting reactive gas A in this manner may be eliminated. In other embodiments, the valve 610a (e.g., Valve N1) corresponding to a first inert gas (e.g., inert gas N1) may be opened to introduce inert gas N1 into the reactors 602 while the exhaust valve remains open. This may serve to purge any residual first reactive gas (e.g., reactive gas A) remaining in the reaction chamber of the reactors 602.

Once reactive gas A is purged by the flow of inert gas N1, Valve N1 may be closed while Valve E2 is kept open. This may serve to exhaust the remaining inert gas N1 before introducing a second reactive gas. In some embodiments, exhausting inert gas N1 in this manner may be eliminated.

Once the second reactive gas is ready to be introduced, the first gas valve 611a of the second set of gas valves (e.g., Valve B) corresponding to the second reactive gas (e.g., reactive gas B) may be opened to introduce reactive gas B into the reactors 602. In some embodiments, the first exhaust valve 616a (e.g., Valve E1) may be opened at the same time as when Valve B is opened or shortly thereafter (e.g., after a predetermined time lag (Tg)), similar to as described above. By opening Valve E1 simultaneously with Valve B or some time thereafter, laminar flow may created. This may allow the gas, e.g., reactive gas B, to cover and adhere to the wafer 604 with greater uniformity.

After a predetermined time period of ALD processing with the second reactive gas, Valve B may be closed while Valve E1 is left open to exhaust the second reactive gas from the chamber of the reactors 602. In some embodiments, exhausting reactive gas B in this manner may be eliminated. In other embodiments, the valve 611b (e.g., Valve N2) corresponding to a second inert gas (e.g., inert gas N2) may be opened to introduce inert gas N into the reactors 602 while Valve E1 remains open. This may serve to purge any residual second reactive gas (e.g., reactive gas B) remaining in the reaction chamber of the reactors 602.

Once reactive gas B is purged by the flow of inert gas N, the valve N may be closed while Valve E1 is kept open. This may serve to exhaust the remaining inert gas N2. In some embodiments, exhausting inert gas N2 in this manner may be eliminated. At this point, one cycle may be completed and subsequent cycles may commence.

It should be appreciated that while embodiments of the present disclosure are directed to exhausting reactive and/or inert gases to each side by opening Valve E1 or Valve E2, in some embodiments, those gases may be exhausted to both sides by opening Valve E1 and E2 simultaneously for the faster ventilation of those gases. It also should be appreciated that while embodiments of the present disclosure are directed to purging reactive gas A and B with inert gas by opening Valve N1 or Valve N2 differently, in some embodiments, the inert gas may be supplied at both sides of the reactor by opening both of Valve N1 and Valve N2 simultaneously for faster ventilation of reactive gases. Other various embodiments may also be provided.

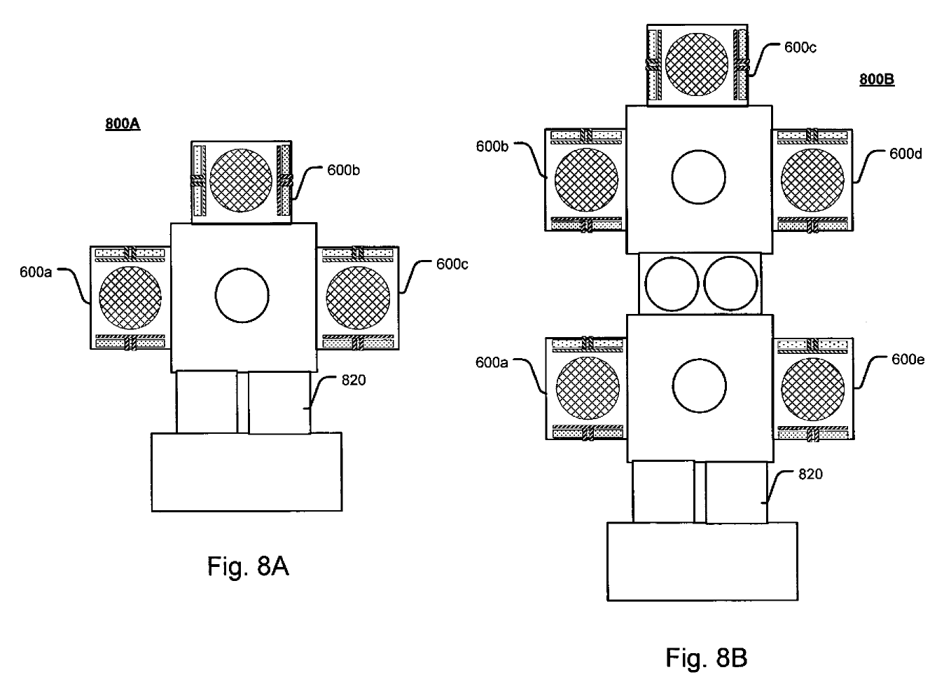

FIGS. 8A-8B depict various exemplary atomic layer deposition (ALD) setups according to additional embodiments of the present disclosure. Referring to FIG. 8A, an ALD setup 800A may comprise three (3) ALD configurations 600a, 600b, and 600c. Referring to FIG. 8B, an ALD setup 800B may comprise five (S) ALD configurations 600a, 600b, 600c, 600d, and 600e. Therefore, in addition to productivity advantages discussed above, these setups 800A, 800B and other similar setup configurations may be provided to further increase ALD productivity in an efficient manner.

It should also be appreciated that wafer load locks 820 may be provided to secure wafers for single, batch, or semi-batch wafer processing. In addition, it should be appreciated that wafer handling may be achieved robotically, manually, or a combination thereof. In some embodiments, the setups 800A, 800B may also be equipped with additional features to optimize ALD processing. For example, load locks 820 may be equipped with the pre-heating/cooling to prepare wafers for ALD processing so that additional pre-heat/cooling time at each ALD reactor may be minimized. In other embodiments, post-heating/cooling may also be provided. For example, high temperature wafers may be cooled before being transferred to a wafer station at atmospheric temperature. Other pre-/post-treatment systems may also be provided in setups 800A, 800B to optimize ALD processing. Other various embodiments may also be provided.

It should be appreciated that while embodiments of the present disclosure are directed to ALD configurations havng stacks of eight (8) reactors, other various configurations may be provided as well. For example, a greater or lesser number of reactors may be stacked to optimize volume, time, and production needs. Furthermore, it should be appreciated that each reactor may be integrally attached to and/or removable from each other in the ALD configuration. It should also be appreciated that each reactor may be equipped with a rotating wafer holder (not shown) to hold and/or rotate the wafer for optimal uniformity during ALD processing.

It should also be appreciated that while embodiments of the present disclosure are directed towards ALD, other implementations, systems, and/or modes of operation may also be provided. These may include chemical vapor deposition (CVD), etching, etc.

It should also be appreciated that while embodiments of the present disclosure are described using two reactive gases and one inert gas, a greater or lesser number/types of gases may also be provided.

It should further be appreciated that the disclosed embodiments not only provide several modes of operation, but that these various modes may provide additional implantation customizations that would not otherwise be readily provided.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. A system for atomic layer deposition (ALD), the system comprising:
a plurality of reactors in a stacked configuration, wherein each reactor comprises a wafer holding portion for holding a target wafer;
a gas assembly coupled to the plurality of reactors and configured to provide at least one gas to at least one of the plurality of reactors; and
an exhaust assembly coupled to the plurality of reactors and configured to exhaust the at least one gas from the at least one of the plurality of reactors.

2. The system of claim 1, wherein the stacked configuration is a vertically stacked configuration such that the plurality of reactors are stacked on top of one another.

3. The system of claim 1, wherein the stacked configuration is a horizontally stacked configuration such that the plurality of reactors are stacked next to one another.

4. The system of claim 1, wherein the gas assembly comprises:
a first gas inlet configured to provide a first gas to the plurality of reactors;
a second gas inlet configured to provide a second gas to the plurality of reactors; and
a third gas inlet configured to provide a third gas to the plurality of reactors.

5. The system of claim 4, wherein the first gas is a first reactive gas, the second gas is a second reactive gas, and the third gas is an inert gas.

6. The system of claim 4, wherein the gas assembly furthermore comprises a valve assembly coupled to each of the first gas inlet, the second gas inlet, and the third gas inlet, wherein the valve assembly is configured to selectively release at least one of the first gas, the second gas, and the third gas.

7. The system of claim 6, wherein the valve assembly is in a vertical valve configuration, the valve assembly further comprising:
a first set of nozzles configured to selectively release the first gas in a plane substantially parallel to a surface of the target wafer;
a second set of nozzles configured to selectively release the second gas in a plane substantially parallel to a surface of the target wafer; and
a third set of nozzles configured to selectively release the third gas in a plane substantially parallel to a surface of the target wafer;
wherein the first set of nozzles, the second set of nozzles, and the third set of nozzles are stacked on top of each other.

8. The system of claim 6, wherein the valve assembly is in a horizontal valve configuration, the valve assembly further comprising:
a first set of nozzles configured to selectively release the first gas in a plane substantially parallel to a surface of the target wafer;
a second set of nozzles configured to selectively release the second gas in a plane substantially parallel to a surface of the target wafer; and
a third set of nozzles configured to selectively release the third gas in a plane substantially parallel to a surface of the target wafer;
wherein the second set of nozzles is positioned adjacent to the first set of nozzles, and the third set of nozzles is positioned adjacent to the second set of nozzles.

9. The system of system 8, wherein the valve assembly is configured to release gas from the at least one of the first set of nozzles, the second set of nozzles, and the third set of nozzles such that the release gas substantially covers an entire surface of the target wafer.

10. The system of claim 9, wherein the first set of nozzles, the second set of nozzles, and the third set of nozzles are alternatively positioned such that gas released from one nozzle is different than gas released from nozzles immediately adjacent the one nozzle.

11. The system of system 6, wherein the valve assembly uses a rod valve to selectively release at least one of the first gas, the second gas, and the third gas.

12. The system of claim 1, wherein the exhaust assembly comprises a first exhaust line configured to exhaust at least one gas from a side opposite that of where the at least one gas is provided.

13. The system of claim 4, wherein the gas assembly further comprises a fourth gas inlet configured to provide a fourth gas to the plurality of reactors, such that the first gas inlet and the third gas inlet are positioned on a first side of the wafer and the second gas inlet and the fourth gas inlet are positioned on a second side of the wafer, wherein the second side is opposite to the first side.

14. The system of claim 13, wherein the exhaust system further comprises a first exhaust line and a second exhaust line, such that the first exhaust line is positioned on the second side and the second exhaust line is positioned on the first side in order to exhaust gas from the plurality of reactors in a counter-flow scheme to improve uniformity.

15. A method for atomic layer deposition (ALD), the method comprising:
releasing a first gas into a chamber of each of a plurality of reactors in order to provide atomic layer deposition of a first species;
exhausting at least the first gas from the chamber while the first gas is being released into the chamber; and
releasing an inert gas into the chamber to purge the chambers of the first gas.

16. The method of claim 15, further comprising exhausting at least the inert gas from the chamber while the inert gas is being released into the chamber.

17. The method of claim 15, wherein exhausting at least the first gas begins simultaneously with the release of the first gas.

18. The method of claim 15, wherein exhausting at least the first gas begins after a predetermined time lag after the release of the first gas.

19. The method of claim 15, wherein exhausting at least the first gas is continuous once the at least the first gas is exhausted from the chamber while the first gas is being released into the chamber.

20. The method of claim 15, wherein exhausting at least the first gas is achieved from a side of the chamber opposite that of a side where the first gas is released.

21. The method of claim 15, further comprising:
releasing a second gas into the chamber in order to provide atomic layer deposition of a second species;
exhausting at least the second gas from the chamber while the second gas is being released into the chamber; and
releasing an inert gas into the chamber to purge the chamber of the second gas.

22. The method of claim 21, wherein the second gas is released from a side of the chamber opposite that of a side where the first gas is released.

23. The method of claim 21, further comprising exhausting at least the inert gas from the chamber while the inert gas is being released into the chamber.

24. The method of claim 21, wherein exhausting at least the second gas begins simultaneously with the release of the second gas.

25. The method of claim 21, wherein exhausting at least the second gas begins after a predetermined time lag after the release of the second gas.

26. The method of claim 21, wherein exhausting at least the second gas is continuous once the at least second gas is exhausted from the chamber while the second gas is being released into the chamber.

27. The method of claim 21, wherein exhausting gas is achieved from a side of the chamber opposite that of a side where the second gas is released.
